(19) United States
(12) Patent Application Publication
(10) Pub. No.: US 2003/0189260 A1
(43) Pub. Date: Oct. 9, 2003

(54) FLIP-CHIP BONDING STRUCTURE AND METHOD THEREOF

(76) Inventors: HO-MING TONG, TAIPEI (TW); CHUN-CHI LEE, KAOHSIUNG (TW); JEN-KUANG FANG, PINGTUNG HSIEN (TW); MIN-LUNG HUANG, KAOHSIUNG (TW); CHING-HUEI SU, KAOHSIUNG (TW); CHAO-FU WENG, TAINAN (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,323

(22) Filed: Apr. 1, 2003

(30) Foreign Application Priority Data
Apr. 3, 2002 (TW) 91106695

(51) Int. Cl. H01L 23/48; H01L 23/52; H01L 29/40

(52) U.S. Cl. 257/778

(57) ABSTRACT

A flip-chip bonding structure suited for bonding a first connect pad and a second connect pad. The flip-chip bonding structure includes a metal layer, a bump and an adhesion body. The metal layer is placed on the first connect pad. The bump, lead-free material, is placed on the metal layer. The adhesion body, made of lead-free material, is placed on the bump and is bonded onto the second connect pad.

### CROSS REFERENCE TO RELATED APPLICATIONS

This application claims the priority benefit of Taiwan application serial no. 91106695, filed on Apr. 3, 2002.

### BACKGROUND OF INVENTION

1. Field of the Invention

The invention relates in general to a flip-chip bonding structure and a method thereof. More particularly, the invention relates to a flip-chip bonding structure with lead-free bumps and lead-free adhesion bodies and a method thereof.

2. Description of the Related Art

In the field of the semiconductor package, the first level package is principally to mount a chip onto a carrier and to electrically connect the chip with the carrier. Generally speaking, there are three package types: wire-bonding technology, tape-automated-bonding technology (TAB), and flip-chip bonding technology. Whether the tape-automated-bonding technology or the flip-chip bonding technology is used, bumps will be formed onto conductive pads of a wafer during the process for mounting a chip onto a carrier. The bumps serve as a medium of electrical connection between the chip and the carrier.

Nowadays the main material of the bumps is tin-lead alloy because lead is low cost and because the fabricating methods of tin-lead alloy, the process characteristics of tin-lead alloy, tin-lead alloy reaction on other metals, the flux matching tin-lead alloy and so on have been thoroughly researched. Besides, in the field of the flip chip technology, tin-lead alloy plays an important role for welding material, by which a chip can be mounted on a substrate. However, using heavy lead may cause severe damage to human health and pollution of the environment.

### SUMMARY OF INVENTION

It is an objective according to the present invention to provide a flip-chip bonding structure and a method thereof. The flip-chip bonding structure includes at least one bump and at least one adhesion body, both of which are lead-free material. Therefore, the damage to human health and the environmental pollution caused by lead can be mitigated.

To achieve the foregoing and other objectives, the present invention provides a flip-chip bonding structure suited for bonding a first connect pad and a second connect pad. The flip-chip bonding structure includes a metal layer, a bump and an adhesion body. The metal layer is placed on the first connect pad. The bump, lead-free material, is placed on the metal layer. The adhesion body, made of lead-free material, is placed on the bump and is bonded onto the second connect pad.

According to an embodiment of the present invention, the metal layer can be a two-layer type, a three-layer type or a four-layer type. The material of the bump and the adhesion body is, for example, tin, tin-copper alloy, tin-antimony alloy, tin-bismuth alloy, tin-indium alloy, tin-zinc alloy, tin-silver alloy, tin-bismuth-silver alloy, tin-bismuth-antimony alloy, tin-bismuth-zinc alloy, tin-bismuth-indium alloy or tin-silver-copper alloy. Besides, when the material of the adhesion body and the bump is decided upon, the melting point of the chosen material of the adhesion body is preferably lower than that of the chosen material of the bump. Also, the adhesion body can be an electrically conductive adhesive and in the case the gel point of the adhesion body is lower than the melting point of the bump. In addition, the bump is, for instance, ball-like shaped or pillar-like shaped.

To achieve the foregoing and other objectives, the present invention provides a process for fabricating a flip-chip bonding structure suited for bonding a first connect pad and a second connect pad. First, a metal layer is formed on the first connect pad and then a bump, made of lead-free material, is formed on the metal layer. Besides, a pre-adhesion body is formed on the second connect pad. Subsequently, the bump is bonded onto the pre-adhesion body. The pre-adhesion body is defined in the mode before the adhesion body is heated over a melting point if the adhesion body is metal material or over a gel point if the adhesion body is electrically conductive adhesive.

Both the foregoing general description and the following detailed description are exemplary and explanatory only and are not restrictive of the invention, as claimed.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1-4 are schematic cross-sectional views showing a process of fabricating a flip-chip bonding structure according to a preferred embodiment of the present invention;

FIG. 2A is a schematic cross-sectional view showing a flip-chip bonding structure having a two-layer type of metal layer according to another preferred embodiment of the present invention;

FIG. 2B is a schematic cross-sectional view showing a flip-chip bonding structure having a four-layer type of metal layer according to another preferred embodiment of the present invention;

FIG. 5 is a schematic cross-sectional view showing a flip-chip bonding structure having a pillar-like shaped bump according to another preferred embodiment of the present invention.

### DETAILED DESCRIPTION

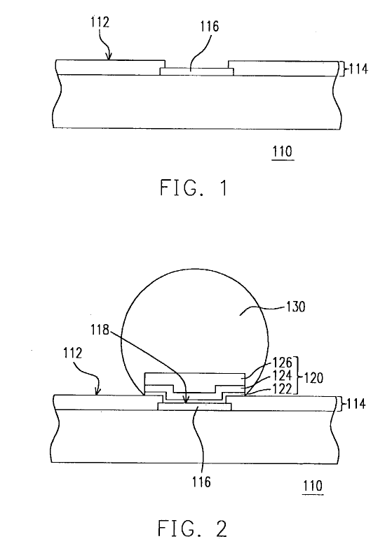

FIGS. 1-4 are schematic cross-sectional views showing a process of fabricating a flip-chip bonding structure according to a preferred embodiment of the present invention. Referring to FIG. 1, a wafer 110 is provided with an active surface 112. The wafer 110 has a passivation layer 114 and many connect pads 116 (only one of them is shown) positioned on the active surface 112 of the chip 110. The passivation layer 114 has many openings exposing the connect pads 116. The passivation layer 114 is, for example, silicon oxide, silicon nitride, phosphosilicate glass (PSG) or a composite layer formed of the above material. In addition, the passivation layer 114 further includes an organic-compound layer, the material of which is, for example, polyimide, and the organic-compound layer is applied at a top layer of the passivation layer 114 to protect the wafer 110.

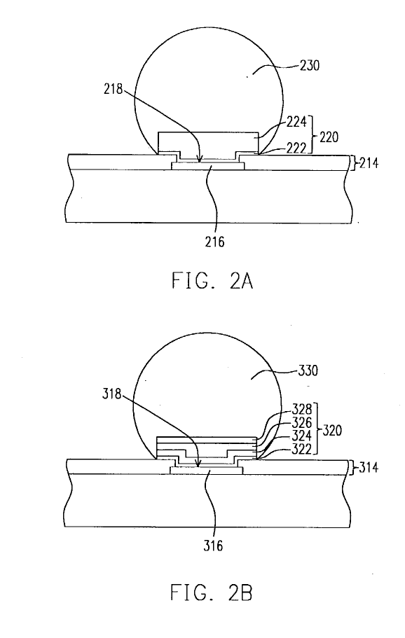

Subsequently, referring to FIG. 2, a sputter process, an evaporation process or an electroplating process can be used to form a metal layer 120 and then a printing process or an electroplating process can be used to form bumps 130 (only one of them is shown). The process of manufacturing the metal layer 120 and the bumps 130 is apparent from and elucidated with reference to R.O.C. patent No. 91,102,775, R.O.C. patent No. 91,102,870, R.O.C. patent No. 91,102,993, R.O.C. patent No. 91,103,529, R.O.C. patent No. 91,103,530, R.O.C. patent No. 91,103,531, R.O.C. patent No. 91,103,532, and R.O.C. patent No. 91,103,533. The process of manufacturing the metal layer 120 and the bumps 130 will not be repeated herein. The configuration of completing the metal layer 120 and the bumps 130 is shown in FIG. 2, wherein the bumps 130 are ball-like shaped. Referring to FIG. 2, the metal layer 120 is, for example, a three-layer type, constructed of a first conductive layer 122, a second conductive layer 124 and a third conductive layer 126, respectively. The first conductive layer 122 is formed on the surface 118 of the connect pads 116 and on the passivation layer 114 surrounding the connect pads 116. The second conductive layer 124 is formed on the first conductive layer 122. The third conductive layer 126 is formed on the second conductive layer 124. The bumps 130 are formed on the third conductive layer 126 and are of lead-free material, such as tin, tin-copper alloy, tin-antimony alloy, tin-bismuth alloy, tin-indium alloy, tin-zinc alloy, tin-silver alloy, tin-bismuth-silver alloy, tin-bismuth-antimony alloy, tin-bismuth-zinc alloy, tin-bismuth-indium alloy, tin-silver-copper alloy and so on. The material and the applying situation of the first conductive layer 122, the second conductive layer 124, and the third conductive layer 126 are detailed below.

In one case, the first conductive layer 122 is formed of titanium, the second conductive layer 124 is formed of titanium nitride, and the third conductive layer 126 is formed of copper, palladium, or gold. In another case, the first conductive layer 122 is formed of tantalum, the second conductive layer 124 is formed of tantalum nitride, and the third conductive layer 126 is formed of copper, palladium, or gold. In another case, the first conductive layer 122 is formed of aluminum, titanium, titanium-tungsten alloy, tantalum, chromium or copper, the second conductive layer 124 is formed of nickel-vanadium alloy or nickel, and the third conductive layer 126 is formed of copper, palladium, or gold. The first conductive layer 122 formed of aluminum is fitted for depositing on the connect pads 116 formed of aluminum, but the first conductive layer 122 formed of copper is fitted for depositing on the connect pads 116 formed of copper. In the other case, the first conductive layer 122 is formed of copper, the second conductive layer 124 is formed of chromium-copper alloy, and the third conductive layer 126 is formed of copper. The first conductive layer 122 is fitted for depositing on the connect pads 116 formed of copper.

The above metal layer is a three-layer type. However, the present invention is not limited to the above application, but the metal layer also can be a two-layer type or a four-layer type, as shown in FIGS. 2A and 2B. FIG. 2A is a schematic cross-sectional view showing a flip-chip bonding structure having a two-layer type of metal layer according to another preferred embodiment of the present invention. FIG. 2B is a schematic cross-sectional view showing a flip-chip bonding structure having a four-layer type of metal layer according to another preferred embodiment of the present invention.

Referring to FIG. 2A, the metal layer is a two-layer type, constructed of a first conductive layer 222 and a second conductive layer 224, respectively. The first conductive layer 222 is formed on the surface 218 of the connect pads 216 and on a passivation layer 214 surrounding the connect pads 216. The second conductive layer 224 is formed on the first conductive layer 222. The first conductive layer 222 is, for example, formed of titanium, titanium-tungsten alloy, chromium or tantalum and the second conductive layer 224 is, for example, formed of copper, palladium, or gold. Bumps 230 (only one of them is shown) are formed on the second conductive layer 224.

Referring to FIG. 2B, the metal layer 320 is a four-layer type, constructed of a first conductive layer 322, a second conductive layer 324, a third conductive layer 326, and a forth conductive layer 328, respectively. The first conductive layer 322 is formed on a surface 318 of the connect pads 316 and on a passivation layer 314 surrounding the connect pads 316. The second conductive layer 324 is formed on the first conductive layer 322. The third conductive layer 326 is formed on the second conductive layer 324. The forth conductive layer 328 is formed on the third conductive layer 326. Bumps 330 (only one of them is shown) are formed on the forth conductive layer 328. The first conductive layer 322 is, for example, formed of chromium-copper alloy, the second conductive layer 324 is, for example, formed of copper, the third conductive layer 326 is, for example, formed of chromium-copper alloy, and the forth conductive layer 328 is, for example, formed of copper. The above four-layer type of the metal layer 320 is fitted for being deposited on the connect pads 316 formed of copper.

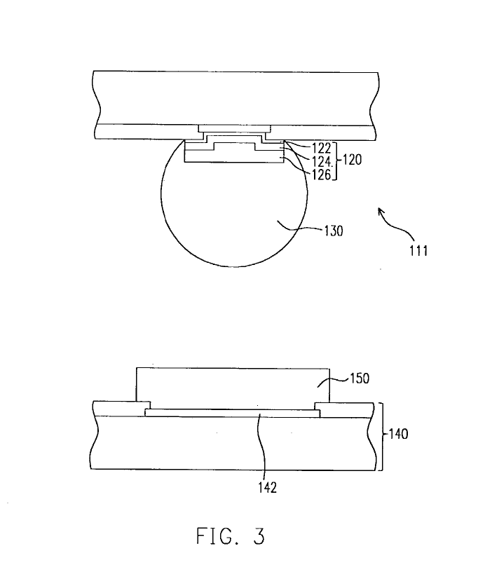

Referring to both FIG. 2 and FIG. 3, after the process of fabricating the metal layer 120 and the bumps 130 is completed, a diamond saw or a laser can be used to cut the wafer 110 all the way through along scribe lines and so many independent chips 111 can be manufactured. Subsequently, a screen-printing process is used to coat pre-adhesion bodies 150 (only one of them is shown), paste-like shaped, on connect pads 142 (only one of them is shown) of a substrate 140. The pre-adhesion bodies 150 can be, for example, solder paste or electrically conductive adhesive. The pre-adhesion bodies 150 are defined in the mode before the adhesion bodies are heated over a melting point if the adhesion bodies are metal material or over a gel point if the adhesion bodies are electrically conductive adhesive. In the case where the pre-adhesion bodies 150 are solder paste, each of the pre-adhesion bodies 150 includes metal particles and flux. The metal particles, such as tin, tin-copper alloy, tin-antimony alloy, tin-bismuth alloy, tin-indium alloy, tin-zinc alloy, tin-silver alloy, tin-bismuth-silver alloy, tin-bismuth-antimony alloy, tin-bismuth-zinc alloy, tin-bismuth-indium alloy or tin-silver-copper alloy, are mixed with the flux. In the case where the pre-adhesion bodies 150 are electrically conductive adhesive, each of the pre-adhesion bodies 150 includes metal particles and adhesive. The metal particles, such as tin, tin-copper alloy, tin-antimony alloy, tin-bismuth alloy, tin-indium alloy, tin-zinc alloy, tin-silver alloy, tin-bismuth-silver alloy, tin-bismuth-antimony alloy, tin-bismuth-zinc alloy, tin-bismuth-indium alloy or tin-silver-copper alloy, are mixed with the adhesive.

It should be noted that the melting point of the bumps 130 is higher than the bonding temperature of the pre-adhesion bodies 150. In the case where the pre-adhesion bodies 150 are solder paste, the melting point of the metal particles mixed in the pre-adhesion bodies 150 is preferably lower than that of the bumps 130. In the case where the pre-adhesion bodies 150 are electrically conductive adhesive, the gel point of the pre-adhesion bodies 150 is lower than the melting point of the bumps 130.

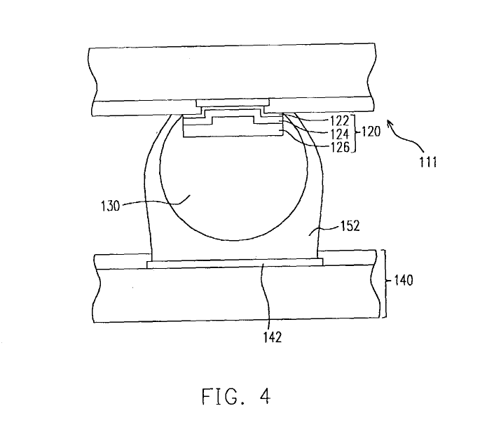

After the pre-adhesion bodies 150 are formed on the connect pads 142 of the substrate 140, the bumps 130 are respectively aligned with the connect pads 142 of the substrate 140 i.e. the pre-adhesion bodies 150. Next, the bumps 130 are pressed on the pre-adhesion bodies 150, respectively. Subsequently, a heating process is performed to solidify the pre-adhesion bodies 150 and then adhesion bodies 152 (only one of them is shown) are formed to bond the bumps 130 onto the connect pads 142 of the substrate 140. During the heating process for solidifying the pre-adhesion bodies 150, the bumps 130 can not be melted and collapsed because the melting point of the bumps 130 is higher than the bonding temperature of the pre-adhesion bodies 150. In the case where the pre-adhesion bodies 150 are solder paste, the metal particles in the pre-adhesion bodies 150 are melted during the heating process and then the melted metal is solidified together to become adhesion bodies 152 during a cooling process. At this moment, the flux flows to the surface of the adhesion bodies 152. Next, a solvent is used to remove the flux on the surface of the adhesion bodies 152. The bumps 130 can be bonded onto the connect pads 142 of the substrate 140 by the adhesion bodies 152. In the case where the pre-adhesion bodies 150 are electrically conductive adhesive, the pre-adhesion bodies 150 are preferably thermosetting. After the pre-adhesion bodies 150 are solidified, the chip 111 can be fastened with the substrate 140 and electrically connected therewith, as shown in FIG. 4.

Referring to FIG. 4, the flip-chip bonding structure of the present invention includes bumps 130 and adhesion bodies 152, all of which are lead-free material. Therefore, the damage to human health and the environmental pollution caused by lead can be mitigated.

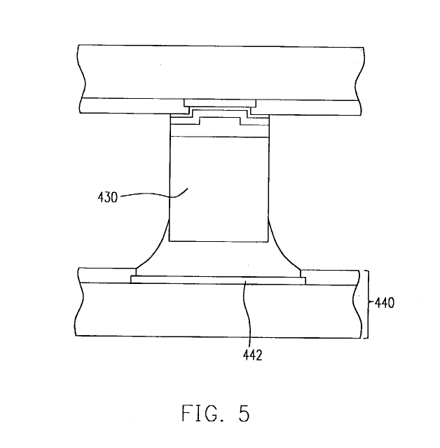

In the above embodiments, the bumps are ball-shaped. However, the present invention is not limited to the ball-like shaped bumps, the bumps also can be pillar-shaped, as shown in FIG. 5, a schematic cross-sectional view showing a flip-chip bonding structure having a pillar-shaped bump according to another preferred embodiment of the present invention. Referring to FIG. 5, the bumps 430 (only shown one of them) are pillar-shaped and are formed, for example, by an electroplating process. Compared with the process for fabricating the above ball-shaped bumps, a reflow process can be saved in the process for fabricating the pillar-shaped bumps 430. In other words, after the reflow process is performed, the pillar-shaped bumps 430 are turned into the above ball-shaped bumps. The material of the bumps 430 and the process of bonding the bumps 430 onto the connect pads 442 of the substrate 440 are similar with the above embodiment and, thus, is not described any more herein.

In addition, the bumps are not limited to being formed on the active surface of the chip, but after a redistribution layer is formed on the active surface of the wafer, the bumps also can be formed on conductive pads of the redistribution layer. The fabrication of the redistribution layer should be known by those skilled in the art and, thus, is not described any more herein.

To sum up, the flip-chip bonding structure of the present invention includes bumps and adhesion bodies, all of which are lead-free material. Therefore, the damage to human health and the environmental pollution caused by lead can be mitigated.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A flip-chip bonding structure suited for bonding a first connect pad and a second connect pad, the structure comprising:
a metal layer placed on the first connect pad;
a lead-free bump placed on the metal layer; and
a lead-free adhesion body placed on the lead-free bump and bonded onto the second connect pad.

2. The flip-chip bonding structure according to claim 1, wherein the metal layer is provided with a first conductive layer and a second conductive layer, the first conductive layer placed on the first connect pad, the second conductive layer placed on the first conductive layer, the lead-free bump placed on the second conductive layer, the first conductive layer formed of titanium, titanium-tungsten alloy or tantalum and the second conductive layer formed of copper, palladium, or gold.

3. The flip-chip bonding structure according to claim 1, wherein the metal layer is provided with a first conductive layer, a second conductive layer and a third conductive layer, the first conductive layer placed on the first connect pad, the second conductive layer placed on the first conductive layer, the third conductive layer placed on the second conductive layer, the lead-free bump placed on the third conductive layer, the first conductive layer formed of aluminum, titanium, titanium-tungsten alloy, tantalum, chromium or copper, the second conductive layer formed of titanium nitride, tantalum nitride, nickel-vanadium alloy, nickel or chromium-copper alloy, and the third conductive layer formed of copper, palladium, or gold.

4. The flip-chip bonding structure according to claim 1, wherein the metal layer is provided with a first conductive layer, a second conductive layer, a third conductive layer, and a forth conductive layer, the first conductive layer placed on the first connect pad, the second conductive layer placed on the first conductive layer, the third conductive layer placed on the second conductive layer, the fourth conductive layer placed on the third conductive layer, the lead-free bump formed on the fourth conductive layer, the first conductive layer formed of chromium-copper alloy, the second conductive layer formed of copper, the third conductive layer formed of chromium-copper alloy, and the forth conductive layer formed of copper.

5. The flip-chip bonding structure according to claim 1, wherein the material of the lead-free adhesion body is selected from one of tin, tin-copper alloy, tin-antimony alloy, tin-bismuth alloy, tin-indium alloy, tin-zinc alloy, tin-silver alloy, tin-bismuth-silver alloy, tin-bismuth-antimony alloy, tin-bismuth-zinc alloy, tin-bismuth-indium alloy and tin-silver-copper alloy.

6. The flip-chip bonding structure according to claim 1, wherein the lead-free adhesion body is an electrically conductive adhesive.

7. The flip-chip bonding structure according to claim 6, wherein the melting point of the lead-free bump is higher than the gel point of the lead-free adhesion body.

8. The flip-chip bonding structure according to claim 1, wherein the melting point of the lead-free bump is higher than the meting point of the lead-free adhesion body made of metal.

9. The flip-chip bonding structure according to claim 1, wherein the second connect pad is placed on a substrate.

10. The flip-chip bonding structure according to claim 1, wherein the first connect pad is placed on a chip or on a redistribution layer that is placed on a chip.

11. The flip-chip bonding structure according to claim 1, wherein the lead-free bump is pillar-shaped or ball-shaped.

12. The flip-chip bonding structure according to claim 1, wherein the material of the lead-free bump is selected from one of tin, tin-copper alloy, tin-antimony alloy, tin-bismuth alloy, tin-indium alloy, tin-zinc alloy, tin-silver alloy, tin-bismuth-silver alloy, tin-bismuth-antimony alloy, tin-bismuth-zinc alloy, tin-bismuth-indium alloy and tin-silver-copper alloy.

13. A flip-chip connection structure, comprising:
a connect pad;
a metal layer placed on the connect pad; and
a lead-free bump placed on the metal layer.

14. The flip-chip connection structure according to claim 13, wherein the metal layer is provided with a first conductive layer and a second conductive layer, the first conductive layer placed on the connect pad, the second conductive layer placed on the first conductive layer, the lead-free bump placed on the second conductive layer, the first conductive layer formed of titanium, titanium-tungsten alloy or tantalum and the second conductive layer formed of copper, palladium, or gold.

15. The flip-chip connection structure according to claim 13, wherein the metal layer is provided with a first conductive layer, a second conductive layer and a third conductive layer, the first conductive layer placed on the connect pad, the second conductive layer placed on the first conductive layer, the third conductive layer placed on the second conductive layer, the lead-free bump placed on the third conductive layer, the first conductive layer formed of aluminum, titanium, titanium-tungsten alloy, tantalum, chromium or copper, the second conductive layer formed of titanium nitride, tantalum nitride, nickel-vanadium alloy, nickel or chromium-copper alloy, and the third conductive layer formed of copper, palladium, or gold.

16. The flip-chip connection structure according to claim 13, wherein the metal layer is provided with a first conductive layer, a second conductive layer, a third conductive layer, and a fourth conductive layer, the first conductive layer placed on the connect pad, the second conductive layer placed on the first conductive layer, the third conductive layer placed on the second conductive layer, the fourth conductive layer placed on the third conductive layer, the lead-free bump formed on the fourth conductive layer, the first conductive layer formed of chromium-copper alloy, the second conductive layer formed of copper, the third conductive layer formed of chromium-copper alloy, and the fourth conductive layer formed of copper.

17. The flip-chip connection structure according to claim 13, wherein the connect pad is placed on a chip or on a redistribution layer that is placed on a chip.

18. The flip-chip connection structure according to claim 13, wherein the lead-free bump is pillar-shaped or ball-shaped.

19. The flip-chip connection structure according to claim 13, wherein the material of the lead-free bump is selected from one of tin, tin-copper alloy, tin-antimony alloy, tin-bismuth alloy, tin-indium alloy, tin-zinc alloy, tin-silver alloy, tin-bismuth-silver alloy, tin-bismuth-antimony alloy, tin-bismuth-zinc alloy, tin-bismuth-indium alloy and tin-silver-copper alloy.

20. A flip-chip connection process suited for connecting a first connect pad and a second connect pad, the process comprising the steps of:
forming a metal layer on the first connect pad;
forming a lead-free bump on the metal layer;
forming a lead-free pre-adhesion body on the second connect pad; and
connecting the lead-free bump with the lead-free pre-adhesion body.

21. The flip-chip connection process according to claim 20, wherein the lead-free pre-adhesion body includes metal particles and flux, the metal particles mixed with the flux, the material of the metal particles being selected from one of tin, tin-copper alloy, tin-antimony alloy, tin-bismuth alloy, tin-indium alloy, tin-zinc alloy, tin-silver alloy, tin-bismuth-silver alloy, tin-bismuth-antimony alloy, tin-bismuth-zinc alloy, tin-bismuth-indium alloy and tin-silver-copper alloy.

22. The flip-chip connection process according to claim 20, wherein the lead-free pre-adhesion body is an electrically conductive adhesive.

23. The flip-chip connection process according to claim 22, wherein the melting point of the lead-free bump is higher than the gel point of the lead-free pre-adhesion body.

24. The flip-chip bonding process according to claim 20, wherein the melting point of the lead-free bump is higher than the melting point of the lead-free adhesion body made of metal.

25. The flip-chip connection process according to claim 20, wherein the material of the lead-free bump is selected from one of tin, tin-copper alloy, tin-antimony alloy, tin-bismuth alloy, tin-indium alloy, tin-zinc alloy, tin-silver alloy, tin-bismuth-silver alloy, tin-bismuth-antimony alloy, tin-bismuth-zinc alloy, tin-bismuth-indium alloy and tin-silver-copper alloy.
